(19) United States
(12) Patent Application Publication
(10) Pub. No.: US 2024/0244791 A1
(43) Pub. Date: Jul. 18, 2024

(54) TOP COVER STRUCTURE FOR LIQUID COOLING BOX BODY OF DATA ROOM

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN)

(21) Appl. No.: 18/402,337

(22) Filed: Jan. 2, 2024

(30) Foreign Application Priority Data
Jan. 12, 2023 (CN) 202310041558.3

(51) Int. Cl. H05K 7/20

(52) U.S. Cl. CPC H05K 7/20327; H05K 7/20763

(57) ABSTRACT

The present disclosure discloses a top cover structure for a liquid cooling box body of a data room, which at least includes a box body and a top cover. One side of the top cover is hinged with the box body and can cover an opening of the box body. Each of the top cover and the box body is provided with a clamping piece that can be clamped to a connecting piece. When two ends of the connecting piece are respectively clamped to the two clamping pieces positioned on the top cover and the box body, a downward pressure applied to the top cover can be provided.

### CROSSREFERENCE TO RELATED APPLICATION

This application claims priority to Chinese Patent Application No. 202310041558.3, titled “TOP COVER STRUCTURE FOR LIQUID COOLING BOX BODY OF DATA ROOM” and filed to the China National Intellectual Property Administration on Jan. 12, 2023, the entire contents of which are incorporated herein by reference.

### TECHNICAL FIELD

The present disclosure relates to the field of a liquid cooling box body, and more particularly, to a top cover structure for the liquid cooling box body of a data room.

### BACKGROUND

Modern data centers undertake a large amount of data computation and storage, which requires increasingly higher system performance stability. To provide higher energy efficiency to meet needs for business development, heat dissipation of servers and even computer rooms has become crucial. As is well known, if the heat dissipation is poor, high temperature not only reduces operating stability of chips, but also generates excessive thermal stress due to temperature difference between internal environment and external environment of modules, which adversely affects electrical performance, operating frequency, mechanical strength, and reliability of the chips.

Compared to traditional air conditioning systems, the most popular liquid cooling technology in the current industry is more advantageous in solving the problem of “heat dissipation of data centers with high heat density”. This liquid cooling technology is quicker in temperature reduction, lower in energy consumption, and is most friendly to environment.

Liquid cooling refers to a cooling method that uses a liquid with higher specific heat capacity as a working fluid for heat transfer to meet needs for heat dissipation of IT equipment such as servers. Common liquid cooling technologies include immersion cooling, spray cooling, and cold plate cooling.

To ensure normal operation of a liquid cooling box body, it is required to ensure airtightness of the box body. This is because leakage of the liquid cooling box body may cause damage to key components such as chips, and also may cause serious damage to the liquids inside the box body, thus having severe consequences.

Most of the existing liquid cooling box bodies are provided with hinges or other small locking pieces for sealing. However, because areas that can be compressed are smaller and scattered, increasing the airtightness of the liquid cooling box bodies by increasing number of the locking pieces may lead to decrease in efficiency of opening and closing the liquid cooling box bodies for operation and maintenance staff.

### SUMMARY

Objectives of the present disclosure are to provide a top cover structure for a liquid cooling box body of a data room, which can increase efficiency of opening and closing the liquid cooling box body while ensuring its airtightness.

To achieve the above objectives, in one aspect the present disclosure provides a top cover structure for a liquid cooling box body of a data room, which at least includes a box body and a top cover. One side of the top cover is hinged with the box body and can cover an opening of the box body. Each of the top cover and the box body is provided with a clamping piece that can be clamped to a connecting piece. When two ends of the connecting piece are respectively clamped to the two clamping pieces positioned on the top cover and the box body, a downward pressure applied to the top cover can be provided.

As a further improvement of the above technical solutions, the connecting piece is provided with a bending structure fitting with an edge of the box body, such that the connecting piece can come into contact with an outer wall of the box body.

As a further improvement of the above technical solutions, the clamping piece at least includes a fastener having a clamping slot for clamping an end of the connecting piece.

As a further improvement of the above technical solutions, the clamping piece positioned on the box body also includes a supporting part, where the supporting part is rotatably arranged on the box body, and a free end of the supporting part is connected to the fastener, such that a preset distance exists between the fastener and a side wall of the box body.

As a further improvement of the above technical solutions, the preset distance is greater than a width of the fastener.

As a further improvement of the above technical solutions, a sealing platform is provided around the opening of the box body, and a bottom surface of the sealing platform is provided with a mounting rack, where the mounting rack has a bearing space for placement of a clamping piece mounting plate, an end of the clamping piece mounting plate is provided with a clamping piece connecting plate extending towards an outer wall of the sealing platform, and the clamping piece is arranged on the clamping piece connecting plate.

As a further improvement of the above technical solutions, a size of the top cover matches the sealing platform, and a side wall of the sealing platform is flush with a side wall of the top cover.

As a further improvement of the above technical solutions, the top cover is at least provided with two clamping pieces, and the two clamping pieces are symmetrically arranged with a central axis of the top cover as a reference mirror.

As a further improvement of the above technical solutions, a spacing exists between the two clamping pieces positioned on the top cover, and the spacing is greater than twice the preset distance.

As can be seen, in the technical solutions provided by the present disclosure, each of the box body and the top cover is provided with a clamping piece that can be clamped to a connecting piece. In this way, when the two ends of the connecting piece are respectively clamped to the two clamping pieces positioned on the same side of the box body, a downward pressure can be provided to most areas of the top cover to compress the top cover to prevent gas and liquid from flowing out of the box body, thereby improving airtightness of the liquid cooling box body.

Furthermore, a preset distance greater than the width of the fastener exists between the fastener of the clamping piece and the box body, such that the connecting piece can be detached from or clamped to the clamping piece on the top cover through horizontal movement, which improves convenience of using the connecting piece, thereby increasing efficiency of opening and closing the top cover.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic diagram of a usage status of a clamping piece according to an embodiment of the present disclosure;

FIG. 2 is a side view of a liquid cooling box body according to an embodiment of the present disclosure;

FIG. 3 is a schematic axonometric diagram of the liquid cooling box body according to another embodiment of the present disclosure;

FIG. 4 is a side view of the liquid cooling box body according to still another embodiment of the present disclosure; and

FIG. 5 is a schematic diagram of a usage status of a clamping piece connecting plate according to an embodiment of the present disclosure.

Reference numerals in the accompanying drawings:

box body 1; top cover 2; connecting piece 3; clamping piece 4; clamping piece mounting plate 5; clamping piece connecting plate 6; sealing platform 7; and mounting rack 8.

### DETAILED DESCRIPTION

Detailed description of embodiments of the present disclosure will further be made below with reference to the accompanying drawings to make the objectives, technical solutions and advantages of the present disclosure more apparent. Terms such as “upper” , “above” , “lower” , “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “slidably connected”, “fixed” and “sleeved” should be understood in a broad sense. For example, the “connection” maybe a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

The technical solutions in the embodiments of the present disclosure will be clearly and completely described below with reference to the accompanying drawings. Apparently, the embodiments described in the present disclosure are some but not all of the embodiments of the present disclosure. All other embodiments obtained by a person of ordinary skill in the art based on the embodiments of the present disclosure without creative efforts shall fall within the protection scope of the present disclosure.

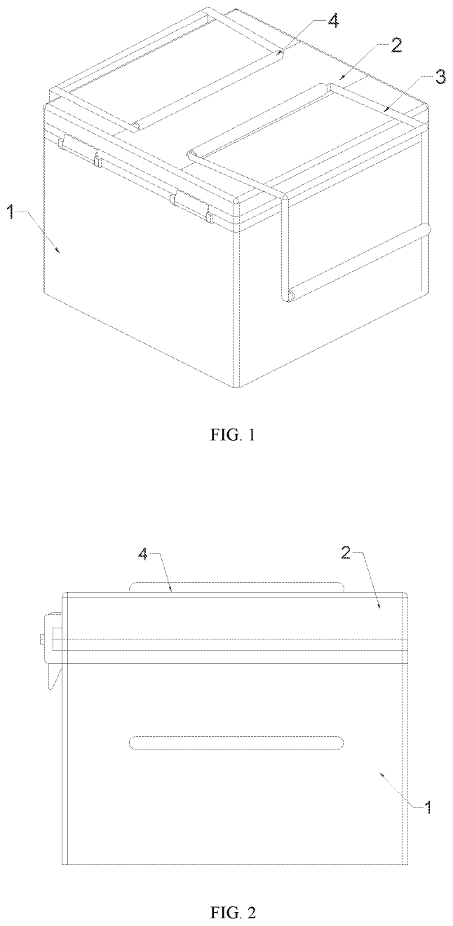

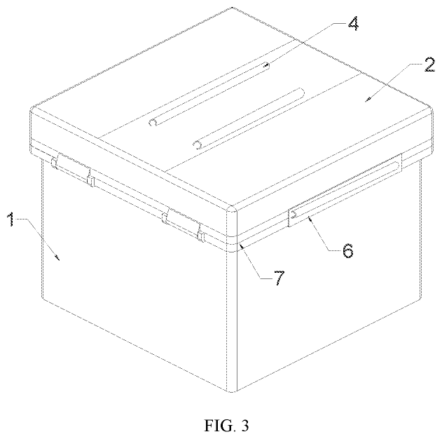

In an implementable embodiment, as shown in FIG. 1 and FIG. 2, a top cover structure for a liquid cooling box body of a data room may at least include a box body 1 and a top cover 2. The top cover 2 can cover an opening of box body 1 through its size. To ensure airtightness of the liquid cooling box body, hinges or other small locking pieces that can match with each other may be arranged on the box body 1 and the top cover 2. However, because areas that can be compressed are smaller and scattered, increasing the airtightness of the liquid cooling box body by increasing number of the locking pieces may lead to decrease in efficiency of opening and closing the liquid cooling box body for operation and maintenance staff. To solve this problem, the top cover structure for the liquid cooling box body provided in the present disclosure may also include a clamping piece 4. Both the box body 1 and the top cover 2 are provided with the clamping piece 4, which can be clamped to an end of the connecting piece 3. When two ends of the connecting piece 3 are respectively clamped to the two clamping pieces 4, a downward pressure applied by the top cover 2 can be provided.

Specifically, the box body 1 is a hollow structure with an opening facing upwards to ensure that a server can be placed in the box body 1. The box body 1 is filled with non-conducting liquid, which immerses the server and cools the server. A size of the top cover 2 matches the box body 1, and the top cover 2 can rotate above the opening of the box body 1. When the top cover 2 comes into contact with the box body 1, the top cover 2 can cover the opening of the box body 1 to prevent the liquid from flowing out of the box body 1.

In this embodiment, the clamping piece 4 at least includes a fastener, which is C-shaped or in other shape with a clamping slot. The clamping slot on the top cover 2 faces towards an upper surface of the top cover 2, and the clamping slot on the box body 1 faces towards a side wall of the box body 1, making it not easy for the connecting piece 3 clamped into the clamping slot to move and break away.

In practical applications, the top cover 2 is at least provided with two clamping pieces 4, and the two clamping pieces 4 are symmetrically arranged with a central axis of the top cover 2 as a reference mirror, such that the two connecting pieces 3 clamped to the two clamping pieces 4 can cover most of area of the top cover 2. In this way, stressed area of the top cover 2 increases, which can further reduce the spacing between the top cover 2 and the box body 1.

Further, number of the clamping pieces 4 arranged on the box body 1 corresponds to that of the clamping pieces 4 arranged on the top cover 2, and these clamping pieces 4 are positioned on a same center line. The two clamping pieces 4 on the same side of the box body 1 can be clamped through the same connecting piece 3. In order that the connecting piece 3 can be clamped into the fasteners of the two clamping pieces 4, a downward pressure may be applied to the top cover 2 such that the top cover 2 gets close to the box body 1, thereby achieving unilateral compression of the box body 1.

Further, the connecting piece 3 is L-shaped or in other shape that can match the structure of the box body 1. The L-shaped bending structure can match the edge of the box body 1, such that the connecting piece 3 comes into contact with the outer wall of the box body 1, thereby improving stability of the connecting piece 3 clamped.

In an implementable embodiment, the clamping piece 4 positioned on the box body 1 also includes a supporting part, where the supporting part is rotatably arranged on the box body 1, and a free end of the supporting part is connected to the fastener. A length of the supporting part is greater than the width of the fastener. In this way, after the supporting part rotates, a preset distance exists between the fastener and the side wall of the box body 1, and the preset distance is greater than the width of the fastener.

Specifically, when the operation and maintenance staff need to open the top cover 2, they move horizontal parts of the connecting pieces 3 towards a direction away from the clamping piece 4 on the top cover 2. That is, the horizontal parts of the two connecting pieces 3 move relatively. Because the preset distance is greater than the width of the fastener, the supporting part rotates such that the end of the connecting piece 3 can completely break away from the fastener. In this case, the operation and maintenance staff only need to flip the connecting piece 3 that is separated from the clamping piece 4 at one end, such that the connecting piece 3 gets away from the top cover 2. In this way, the top cover 2 can be opened.

In a natural state, one end of the connecting piece 3 is still clamped to the clamping piece 4 on the box body 1, the free end of the supporting part faces downwards, and it is not required to remove the connecting piece 3 wholly.

After the top cover 2 is closed, the operation and maintenance staff first rotate the supporting part such that its free end faces upwards, making it easier for other end of the connecting piece 3 to clamp with the clamping piece 4 on the top cover 2. In this case, the horizontal part of the connecting piece 3 comes into contact with an upper surface of the box body 1, thereby compressing the top cover 2 by the connecting piece 3.

Further, a spacing exists between the two clamping pieces 4 positioned on the top cover 2, and the spacing is greater than twice the preset distance. In this way, when the operation and maintenance staff move the two connecting pieces 3 relative to each other, the spacing can ensure that no collision occurs between the two connecting pieces 3, thereby avoiding mutual influences.

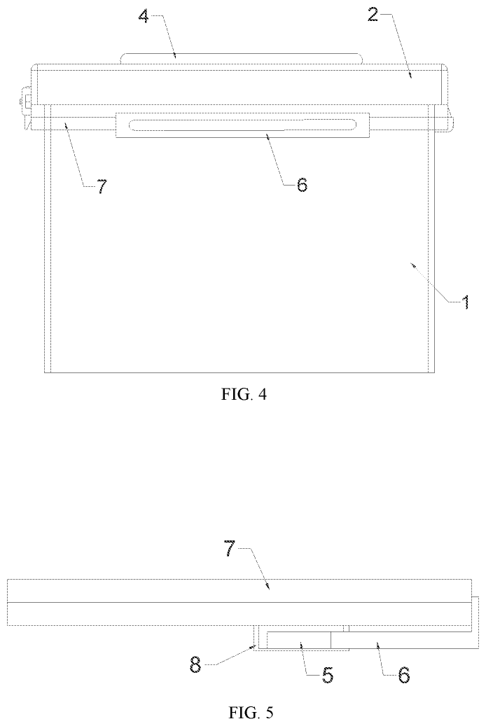

Different from the embodiment where the clamping pieces 4 are fixed on two sides of the box body 1, referring to FIGS. 3 to 5, In another implementable embodiment, a sealing platform 7 is provided around the opening of the box body 1, and a bottom surface of the sealing platform 7 is provided with a mounting rack 8. There is a certain distance between the mounting rack 8 and the sealing platform 7, thereby forming a shape of a bearing space, where a size of the bearing space is larger than that of the clamping piece mounting plate 5. An end of the clamping piece mounting plate 5 is provided with a clamping piece connecting plate 6 extending towards an outer side thereof. The supporting part of the clamping piece 4 is rotatably arranged on the clamping piece connecting plate 6, and the opening of the fastener faces towards a side wall of the sealing platform 7. When the clamping piece mounting plate 5 is placed on the mounting rack 8, both the clamping piece mounting plate 5 and the clamping piece connecting plate 6 can come into contact with the sealing platform 7.

In practical applications, to ensure that the clamping piece connecting plate 6 can attach to the sealing platform 7, thereby improving clamping stability between the connecting piece 3 and the clamping piece 4, the clamping piece connecting plate 6 is provided with a bending structure fitting with an edge of the sealing platform 7. Further, the size of the top cover 2 matches that of the sealing platform 7. While the bottom surface of the top cover 2 covers the opening of the box body 1, the top cover 2 can also fit with the sealing platform 7, such that the side wall of the sealing platform 7 is flush with the side wall of the top cover 2. In this way, when the connecting piece 3 is clamped to the two clamping pieces 4 on the same side, it does not lead to a consequence that failure of clamping is caused by insufficient length of the connecting piece 3 due to far distance between the top cover 2 and the sealing platform 7.

The embodiments set forth above are only illustrated as preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. A top cover structure for a liquid cooling box body of a data room, at least comprising a box body (1) and a top cover (2), wherein one side of the top cover (2) is hinged with the box body (1) and can cover an opening of the box body (1); and
each of the top cover (2) and the box body (1) is provided with a clamping piece (4) that can be clamped to a connecting piece (3); when two ends of the connecting piece (3) are respectively clamped to the two clamping pieces (4) positioned on the top cover (2) and the box body (1), a downward pressure applied to the top cover (2) can be provided.

2. The top cover structure for the liquid cooling box body of the data room according to claim 1, wherein the connecting piece (3) is provided with a bending structure fitting with an edge of the box body (1), such that the connecting piece (3) can come into contact with an outer wall of the box body (1).

3. The top cover structure for the liquid cooling box body of the data room according to claim 1, wherein the clamping piece (4) at least comprises a fastener having a clamping slot for clamping an end of the connecting piece (3).

4. The top cover structure for the liquid cooling box body of the data room according to claim 3, wherein the clamping piece (4) positioned on the box body (1) further comprises a supporting part; and
the supporting part is rotatably arranged on the box body (1), and a free end of the supporting part is connected to the fastener, such that a preset distance exists between the fastener and a side wall of the box body (1).

5. The top cover structure for the liquid cooling box body of the data room according to claim 4, wherein the preset distance is greater than a width of the fastener.

6. The top cover structure for the liquid cooling box body of the data room according to claim 3, wherein a sealing platform (7) is provided around the opening of the box body (1), and a bottom surface of the sealing platform (7) is provided with a mounting rack (8); and
the mounting rack (8) has a bearing space for placement of a clamping piece mounting plate (5), an end of the clamping piece mounting plate (5) is provided with a clamping piece connecting plate (6) extending towards an outer wall of the sealing platform (7), and the clamping piece (4) is arranged on the clamping piece connecting plate (6).

7. The top cover structure for the liquid cooling box body of the data room according to claim 6, wherein a size of the top cover (2) matches the sealing platform (7), and a side wall of the sealing platform (7) is flush with a side wall of the top cover (2).

8. The top cover structure for the liquid cooling box body of the data room according to claim 5, wherein the top cover (2) is at least provided with two clamping pieces (4), and the two clamping pieces (4) are symmetrically arranged with a central axis of the top cover (2) as a reference mirror.

9. The top cover structure for the liquid cooling box body of the data room according to claim 8, wherein a spacing exists between the two clamping pieces (4) positioned on the top cover (2), and the spacing is greater than twice the preset distance.
